(19) United States
(12) Patent Application Publication
(10) Pub. No.: US 2020/0350266 A1
(43) Pub. Date: Nov. 5, 2020

(54) DISPLAY SUBSTRATE, MANUFACTURING METHOD THEREOF AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Shun ZHANG, Beijing (CN); Mengmeng DU, Beijing (CN); Bo CHENG, Beijing (CN)

(21) Appl. No.: 16/643,425

(22) PCT Filed: Aug. 14, 2019
(86) PCT No.: PCT/CN2019/100522

§ 371 Date: Feb. 28, 2020

(30) Foreign Application Priority Data
Aug. 17, 2018 (CN) 201810942476.5

(51) Int. Cl. H01L 23/58; H01L 27/12

(52) U.S. Cl. CPC H01L 23/585; H01L 27/127; H01L 27/3244; H01L 27/124; H01L 27/1288

(57) ABSTRACT

A display substrate, a manufacturing method and a display device are provided. The display substrate includes a functional region and a peripheral region surrounding the functional region. A barrier structure is arranged at the peripheral region of the display substrate, and includes a plurality of barrier members spaced from each other in a direction away from the functional region. At least a part of the barrier member are made of metal.

### CROSS-REFERENCE TO RELATED APPLICATIONS

The present application is the U.S. national phase of PCT Application No. PCT/CN2019/100522 filed on Aug. 14, 2019, which claims a priority of the Chinese patent application No. 201810942476.5 filed on Aug. 17, 2018, the disclosures of which are incorporated herein by reference in their entirety.

### TECHNICAL FIELD

The present disclosure relates to the field of display technology, in particular to a display substrate, a manufacturing method thereof and a display device.

### BACKGROUND

Currently, in use, the following problem frequently occurs for a display device: cracks are generated at a periphery of the display device and easily spread to an interior of a back plate of the display device, resulting in a damage to the back plate. In order to solve this problem, in the related art, usually grooves may be formed in an inorganic layer in several circles at the periphery of the back plate, so as to prevent the cracks at the periphery of the back plate from extending to the interior of the back plate. However, due to brittleness of the inorganic layer, it may easily form a channel for the spreading of the cracks while preventing the spreading of the cracks.

### SUMMARY

In one aspect, the present disclosure provides in some embodiments a display substrate, including a functional region and a peripheral region surrounding the functional region. A barrier structure is arranged at the peripheral region of the display substrate, and includes a plurality of barrier members spaced from each other in a direction away from the functional region. At least a part of the barrier member is made of metal. Thicknesses of the barrier members in a direction perpendicular to the display substrate gradually increase in the direction away from the functional region.

In a possible embodiment of the present disclosure, each barrier member includes a first sub-member and a second sub-member laminated one on another, the second sub-member is located at a surface of the first sub-member away from a base substrate of the display substrate, and an orthogonal projection of the second sub-member onto the base substrate is located within an orthogonal projection of the first sub-member onto the base substrate.

In a possible embodiment of the present disclosure, the first sub-members of the barrier members are independent of each other, and the barrier structure further includes a first connection layer configured to connect ends of the second sub-members away from the corresponding first sub-members.

In a possible embodiment of the present disclosure, the barrier structure further includes a plurality of third sub-members arranged at a side of the first connection layer away from the first sub-members and corresponding to the first sub-members in a one-to-one manner, and an orthogonal projection of each third sub-member onto the base substrate is located within the orthogonal projection of the corresponding first sub-member onto the base substrate.

In a possible embodiment of the present disclosure, the barrier structure further includes a second connection layer configured to connect ends of the third sub-members away from the corresponding first sub-members.

In a possible embodiment of the present disclosure, the first sub-members, the second sub-members, the third sub-members, the first connection layer and/or the second connection layer surround the functional region.

In a possible embodiment of the present disclosure, an orthogonal projection of each of the first sub-members, the second sub-members, the third sub-members, the first connection layer and/or the second connection layer onto the base substrate of the display substrate is of a wave shape.

In a possible embodiment of the present disclosure, each first sub-member includes a first sub-pattern and a second sub-pattern arranged at a same layer or different layers, and an orthogonal projection of the first sub-pattern onto the base substrate and an orthogonal projection of the second sub-pattern onto the base substrate together define at least one enclosed region.

In a possible embodiment of the present disclosure, the first sub-members of the barrier members of barrier structure are arranged at different layers and gradually close to the base substrate in the direction away from the functional region, and thicknesses of the second sub-members in the direction perpendicular to the display substrate gradually increase in the direction away from the functional region.

In a possible embodiment of the present disclosure, at least one of the plurality of first sub-members is created from a same layer and made of a same material as a first gate electrode layer of the display substrate, at least one of the plurality of first sub-members is created from a same layer and made of a same material as a second gate electrode layer of the display substrate, and/or at least one of the plurality of first sub-members is created from a same layer and made of a same material as a semiconductor layer of the display substrate.

In a possible embodiment of the present disclosure, the first connection layer is created from a same layer and made of a same material as a source electrode layer and a drain electrode layer of the display substrate, and the second connection layer is created from a same layer and made of a same material as an anode layer of the display substrate.

In a possible embodiment of the present disclosure, the display substrate further includes: a dielectric layer arranged at a side of each first sub-member away from the base substrate and provided with a plurality of first via-holes, the second sub-members being formed in the first via-holes in a one-to-one manner; and a planarization layer arranged at a side of the first connection layer away from the base substrate and provided with a plurality of second via-holes, the third sub-members being formed in the second via-holes in a one-to-one manner.

In a possible embodiment of the present disclosure, the first connection layer is made of a same material as each second sub-member, and the second connection layer is made of a same material as each third sub-member.

In another aspect, the present disclosure provides in some embodiments a display device including the above-mentioned display substrate.

In yet another aspect, the present disclosure provides in some embodiments a manufacturing method for the above-mentioned display substrate, including forming a barrier structure at a peripheral region of the display substrate. The barrier structure of the display substrate includes a plurality of barrier member, and each barrier member includes a first sub-member and a second sub-member. The display substrate further includes a first gate electrode layer, a second gate electrode layer, and a semiconductor layer. The forming the barrier structure at the peripheral region of the display substrate includes: forming at least one of the plurality of first sub-members and the first gate electrode layer through a single patterning process, forming at least one of the plurality of first sub-members and the second gate electrode layer through a single patterning process, and/or forming at least one of the plurality of first sub-members and the semiconductor layer through a single patterning process, the first sub-members of the barrier members being spaced from each other; and forming each second sub-member at a surface of the corresponding first sub-member away from a base substrate of the display substrate, an orthogonal projection of each second sub-member onto the base substrate being located within an orthogonal projection of the corresponding first sub-member onto the base substrate.

In a possible embodiment of the present disclosure, the barrier structure further includes a first connection layer, and the display substrate further includes a dielectric layer. Prior to forming the second sub-members, the forming the barrier structure at the peripheral region of the display substrate further includes: forming the dielectric layer at a surface of each first sub-member away from the base substrate of the display substrate; and patterning the dielectric layer to form a plurality of first via-holes. The forming each second sub-member at the surface of the corresponding first sub-member away from the base substrate of the display substrate includes forming the plurality of second sub-members and the first connection layer through a single patterning process, the plurality of second sub-members being located within the plurality of first via-holes in a one-to-one manner, and the first connection layer being configured to connect ends of the plurality of second sub-members away from the corresponding first sub-members.

In a possible embodiment of the present disclosure, the display substrate further includes a source electrode layer and a drain electrode layer, and the forming the plurality of second sub-members and the first connection layer through a single patterning process includes forming the plurality of second sub-members, the first connection layer, the source electrode layer and the drain electrode layer through a single patterning process.

In a possible embodiment of the present disclosure, the barrier structure further includes a plurality of third sub-members and a second connection layer, and the display substrate further includes a planarization layer. Subsequent to forming the first connection layer, the forming the barrier structure at the peripheral region of the display substrate further includes: forming the planarization layer at a surface of the first connection layer away from the base substrate of the display substrate; patterning the planarization layer to form a plurality of second via-holes corresponding to the first sub-members in a one-to-one manner, an orthogonal of each second via-hole onto the base substrate being located within an orthogonal projection of the corresponding first sub-member onto the base substrate; and forming the plurality of third sub-members and the second connection layer through a single patterning process, the plurality of third sub-members being located within the plurality of second via-holes in a one-to-one manner, and the second connection layer being configured to connect ends of the plurality of third sub-members away from the corresponding first sub-members.

In a possible embodiments of the present disclosure, the display substrate further includes an anode layer, and the forming the plurality of third sub-members and the second connection layer through a single patterning process includes forming the plurality of third sub-members, the second connection layer and the anode layer through a single patterning process.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a schematic view showing a display substrate according to one embodiment of the present disclosure;

FIG. 2 is a schematic view showing the formation of a barrier structure according to one embodiment of the present disclosure;

FIG. 3 is another schematic view showing the formation of the barrier structure according to one embodiment of the present disclosure;

FIG. 4 is yet another schematic view showing the formation of the barrier structure according to one embodiment of the present disclosure; and

FIG. 5 is a schematic view showing a display substrate according to one embodiment of the present disclosure.

Reference Sign List

| | |
|---|---|
| 1-display substrate | 10-functional region |
| 11-peripheral region | 12-barrier structure |
| 120-barrier member | 121-first sub-member |
| 1210- first sub-pattern | 1211-second sub-pattern |
| 122-second sub-member | 123-first connection layer |
| 124-third sub-member | 125-second connection layer |
| 126-first via-hole | 127-second via-hole |
| 128-enclosed region | |

### DETAILED DESCRIPTION

The present disclosure will be described hereinafter in conjunction with the drawings and embodiments.

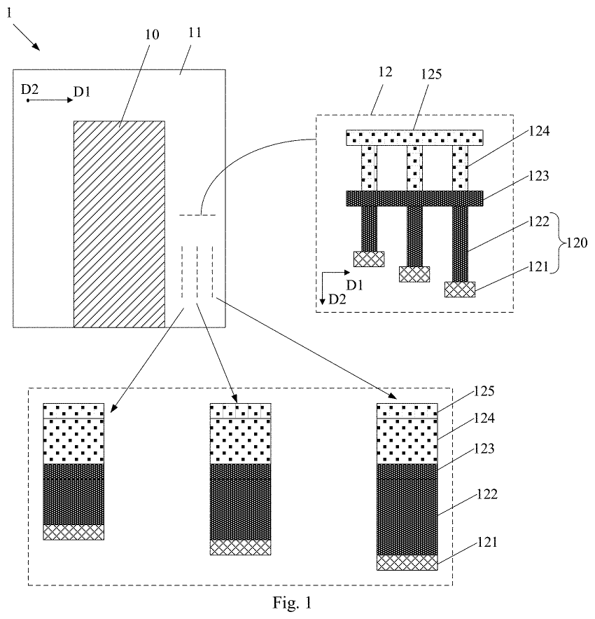

As shown in FIG. 1, the present disclosure provides in some embodiments a display substrate 1, which includes a functional region 10 and a peripheral region 11 surrounding the functional region 10. A barrier structure 12 is arranged at the peripheral region 11 of the display substrate 1, and includes a plurality of barrier members 120 spaced from each other in a direction away from the functional region 10 (i.e., a direction from an interior to an exterior of the display substrate 1 as indicated by D1 in FIG. 1). At least parts of the barrier members 120 are made of metal. It should be appreciated that, in FIG. 1, a horizontal dotted line and three vertical dotted lines at the peripheral region 11 represent cutting lines, and each pattern surrounded by a dotted box corresponding to each dotted line represents a sectional view acquired when a cutting operation is performed along the corresponding dotted line.

To be specific, the functional region 10 of the display substrate 1 may include an active display region and a circuitry region surrounding the active display region. The barrier structure 12 arranged at the peripheral region 11 surrounding the functional region 10 may include the plurality of barrier members 120 spaced apart from each other in the direction away from the functional region 10. The plurality of barrier members 120 may be equivalent to a plurality of retaining walls at the peripheral region 11 of the display substrate 1, so as to stop cracks occurring at a periphery of the display substrate. In addition, each barrier member 120 may be made of various materials, e.g., at least parts of the barrier members 120 may be made of a metallic material.

In actual use, when the cracks occur at the periphery of the display substrate 1, they may spread to the functional region 10 of the display substrate 1. When the cracks reach the barrier structure 12 at the peripheral region 11, they may be stopped by the barrier structure 12 so as not to continuously spread to the functional region of the display substrate 1.

Based on the structure of the display substrate 1 and the actual application thereof, the barrier structure 12 may be arranged at the peripheral region 11 of the display substrate 1 and include the plurality of barrier members 120 spaced apart from each other in the direction away from the functional region 10, so when the cracks spread to the barrier structure 12, they may be stopped by the barrier members 120 of the barrier structure 12 many times. In addition, at least parts of the barrier members 120 may be made of a metallic material having relatively high strength, excellent plasticity and flexibility, so the barrier members may not easily be broken when stopping the cracks, i.e., they may not form channels for the spreading of the cracks. As a result, it is able to provide the display substrate 1 with a better crack-stopping effect, and improve the yield and the reliability of the display substrate 1.

It should be appreciated that, the display substrate 1 may, but not limited to, be applied to an Active Matrix Organic Light-Emitting Diode (AMOLED) display device and function as a back plate thereof, or applied to a liquid crystal display and function as an array substrate thereof.

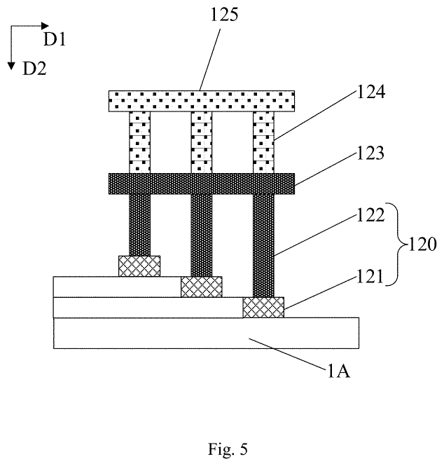

Each barrier member 120 may be of various structures. In some embodiments of the present disclosure, each barrier member 120 may include a first sub-member 121 and a second sub-member 122 laminated one on another, the second sub-member 122 may be located at a surface of the first sub-member 121 away from a base substrate 1A of the display substrate 1 (as shown in FIG. 5), and an orthogonal projection of the second sub-member 122 onto the base substrate 1A may be located within an orthogonal projection of the first sub-member 121 onto the base substrate. In a possible embodiment of the present disclosure, the first sub-member 121 and the second sub-member 122 may be laminated one on another in a direction D2 perpendicular to the base substrate 1A.

To be specific, when each barrier member 120 includes the first sub-member 121 and the second sub-member 122 laminated one on another, it is able to provide the barrier member 120 with a relatively large thickness in the direction perpendicular to the base substrate of the display substrate 1 and thereby provide a larger stopping range in the direction perpendicular to the base substrate. In addition, when the cracks occur for one of the first sub-member 121 and the second sub-member 122, they may not easily spread to the other one, i.e., the other one of the first sub-member and the second sub-member may still stop the spreading of the cracks.

In addition, there may exist various relationships between the orthogonal projection of the second sub-member 122 onto the base substrate and the orthogonal projection of the first sub-member 121 onto the base substrate. For example, the orthogonal projection of the second sub-member 122 onto the base substrate may be located within the orthogonal projection of the first sub-member 121 onto the base substrate. It should be appreciated that, when the orthogonal projection of the second sub-member 122 onto the base substrate is located within the orthogonal projection of the first sub-member 121 onto the base substrate, it may include such a situation where the orthogonal projection of the second sub-member 122 onto the base substrate coincides with the orthogonal projection of the first sub-member 121 onto the base substrate.

Further, the first sub-members 121 of the barrier members 120 may be independent of each other. The barrier structure 12 may further include a first connection layer 123 configured to connect ends of the second sub-members 122 away from the corresponding first sub-members 121.

To be specific, the first connection layer 123 may be arranged at a side of the second sub-member 122 away from the corresponding first sub-member 121, and the ends of the second sub-members 122 away from the corresponding first sub-members 121 may be connected through the first connection layer 123, so as to form the barrier members 120 in a comb-like frame structure. In this way, it is able to improve the firmness of the entire barrier structure 12, and stop the spreading of the cracks through the first connection layer 123, thereby to further improve the crack-stopping effect of the barrier structure 12.

It should be appreciated that, as shown in FIG. 1, when the first sub-members 121 of the barrier members 120 are independent of each other, it means that when the first sub-members 121 are arranged at a same layer, the orthogonal projections of the first sub-members 120 onto the base substrate of the display substrate may be independent of each other, and when they are arranged at different layers, the orthogonal projections of the first sub-members 120 onto the base substrate of the display substrate may be independent of each other or partially overlap each other.

The barrier structure 12 may further include a plurality of third sub-members 124 arranged at a side of the first connection layer 123 away from the first sub-members 121 and corresponding to the first sub-members 121 in a one-to-one manner, and an orthogonal projection of each third sub-member 124 onto the base substrate may be located within the orthogonal projection of the corresponding first sub-member 121 onto the base substrate.

To be specific, the plurality of third sub-members 124 corresponding to the first sub-members 121 in a one-to-one manner may be arranged at a side of the first connection layer 123 away from the first sub-member 121, so as to provide the barrier structure 12 with a larger thickness in the direction perpendicular to the base substrate, thereby to provide a larger stopping range in the direction perpendicular to the base substrate. In addition, the third sub-members 124 may correspond to the first sub-members 121 in a one-to-one manner, and the orthogonal projection of each third sub-member 124 onto the base substrate may be located within the orthogonal projection of the corresponding first sub-member 121 onto the base substrate, so each first sub-member 121 of the barrier structure 12 may correspond to one second sub-member 122 and one third sub-member 124, and each first sub-member 121, the corresponding second sub-member 122 and the corresponding third sub-member 124 may form a straight line approximately in the direction perpendicular to the base substrate, so as to further improve the stopping effect of the barrier structure 12.

It should be appreciated that, when the orthogonal projection of the third sub-member 124 onto the base substrate is located within the orthogonal projection of the corresponding first sub-member 121 onto the base substrate, it may include such a situation where the orthogonal projection of the third sub-member 124 onto the base substrate coincides with the orthogonal projection of the first sub-member 121 onto the base substrate.

It should be appreciated that, the third sub-member 124 may be arranged in such a manner that the orthogonal projection of the third sub-member 124 onto the base substrate partially overlaps or approximately coincides with, apart from being located within, the orthogonal projection of the corresponding first sub-member 121 onto the base substrate.

The barrier structure 12 may further include a second connection layer 125 configured to connect ends of the third sub-members 124 away from the corresponding first sub-members 121.

To be specific, the second connection layer 125 may be arranged at a side of each third sub-member 124 away from the corresponding first sub-member 121, and the ends of the third sub-members away from the corresponding first sub-members 121 may be connected through the third connection layer 125, so as to form another frame structure at a side of the first connection layer 123 away from the base substrate, thereby to further improve the firmness of the entire barrier structure 12. In addition, the spreading of the cracks may also be stopped by the second connection layer 125, so as to further improve the crack-stopping effect of the barrier structure 12.

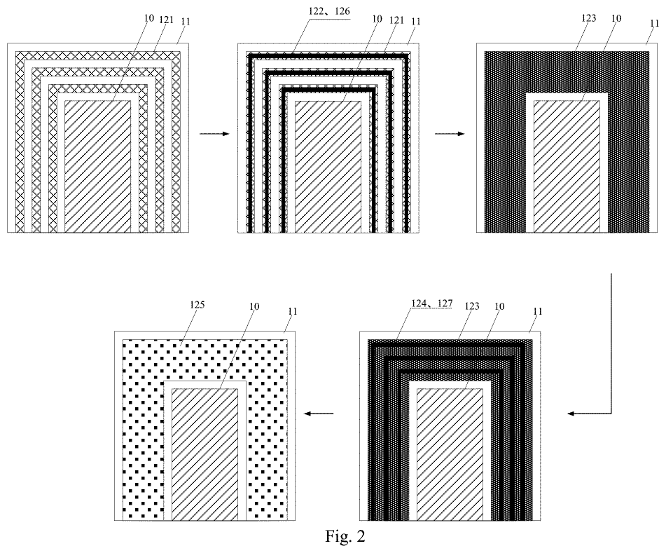

Further, the first sub-members 121, the second sub-members 122, the third sub-members 124, the first connection layer 123 and the second connection layer 125 may each be of various structures. As shown in FIG. 2, the first sub-members 121, the second sub-members 122, the third sub-members 124, the first connection layer 123 and/or the second connection layer 125 may surround the functional region 10.

To be specific, when first sub-members 121, the second sub-members 122, the third sub-members 124, the first connection layer 123 and/or the second connection layer 125 surround the functional region 10, it is able for the barrier structure 12 to completely enclose the functional region 10. In this way, when the cracks at the periphery of the display substrate 1 spread to the functional region 10 of the display substrate at any position, the barrier structure 12 may stop the cracks, so as to prevent the cracks from spreading to the functional region to the greatest extent.

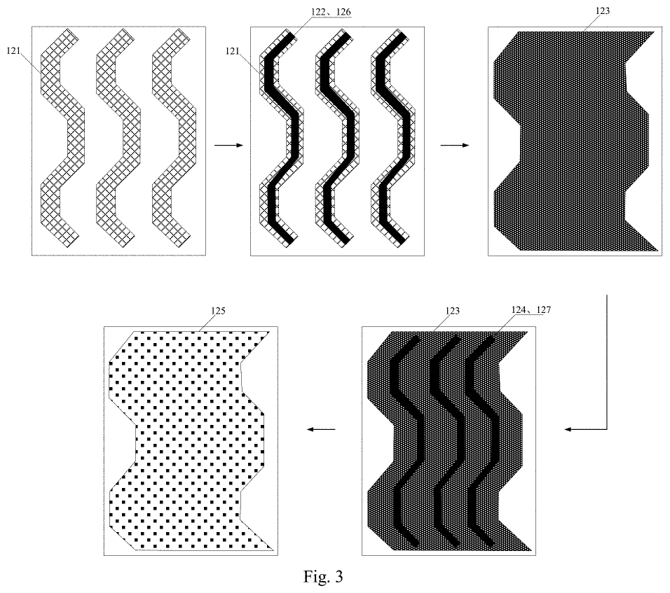

In some embodiments of the present disclosure, as shown in FIG. 3, the orthogonal projection of each of the first sub-members 121, the second sub-members 122, the third sub-members 124, the first connection layer 123 and/or the second connection layer 125 onto the base substrate of the display substrate 1 may be of a wave shape.

To be specific, when the orthogonal projection of each of the first sub-members 121, the second sub-members 122, the third sub-members 124, the first connection layer 123 and/or the second connection layer 125 onto the base substrate of the display substrate 1 is of a wave shape, e.g., a square wave shape or a curved wave shape, it is able to provide the barrier structure 12 with better stress resistance. When the cracks spread to the barrier structure 12, the barrier structure 12 may not easily be broken, so it is able to achieve a better crack-stopping effect.

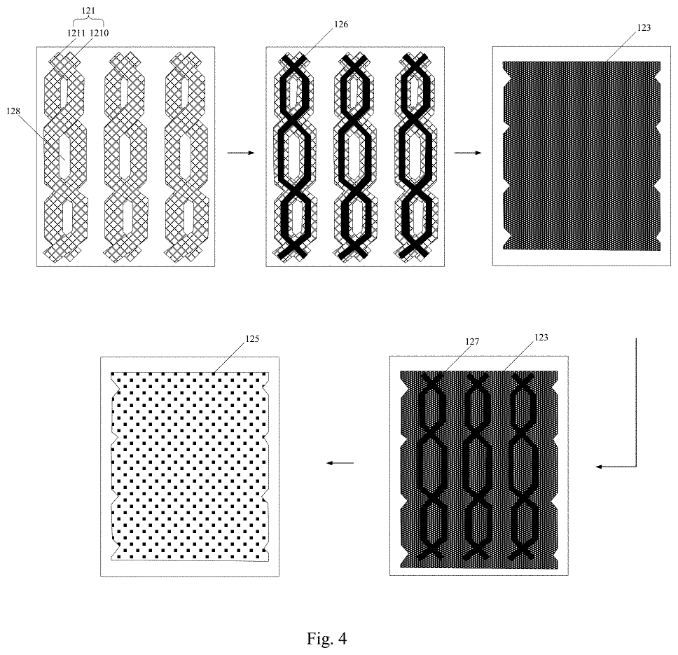

In some embodiments of the present disclosure, as shown in FIG. 4, each first sub-member 121 may include a first sub-pattern 1210 and a second sub-pattern 1211 arranged at a same layer or different layers, and an orthogonal projection of the first sub-pattern 1210 onto the base substrate of the display substrate 1 and an orthogonal projection of the second sub-pattern 122 onto the base substrate of the display substrate 1 may together define at least one enclosed region 128.

To be specific, when the first sub-member 121 is of the above-mentioned structure, it is able to provide a two-layered retaining wall surrounding the enclosed region 128. When the cracks occurring at the periphery of the display substrate 1 spread over a first layer of the retaining wall, they may be stopped by a second layer of the retaining wall, so it is able to improve the crack-stopping effect of the barrier structure 12 through the first sub-member 121 with the above-mentioned structure.

Further, as shown in FIG. 1, the first sub-members 121 of the barrier members 120 of the barrier structure 12 may be arranged at different layers and gradually close to the base substrate in the direction away from the functional region 10, and thicknesses of the second sub-members 122 in the direction perpendicular to the display substrate 1 may gradually increase in the direction away from the functional region 10.

To be specific, based on the above-mentioned barrier structure 12, the thicknesses of the barrier members 120 of the barrier structure 12 in the direction perpendicular to the display substrate 1 may gradually increase in the direction away from the functional region 10, i.e., the stopping ranges of the barrier members 120 in the direction perpendicular to the display substrate 1 may gradually increase. In this way, it is able for the barrier members 120 to stop the spreading of the cracks in a large area at a position close to the periphery of the display substrate 1, and stop the spreading of the cracks in a small area at a position close to the functional region 10 of the display substrate 1. In other words, the barrier structure 12 may stop the cracks occurring at the periphery of the display substrate 1 at a position away from the functional region 10, and still stop the spreading of the cracks at a position close to the functional region 10, so it is able to reduce the manufacture cost of the barrier structure 12 while stopping the spreading of the cracks.

In the barrier structure 12, the sub-members, a material and a position of each of the first connection layer 12 and the second connection layer 125 may be selected according to the practical need, which will be illustratively described hereinafter, but not limited herein.

In some embodiments of the present disclosure, at least one of the plurality of first sub-members 121 may be created from a same layer and made of a same material as the first gate electrode layer of the display substrate 1, at least one of the plurality of first sub-members 121 may be created from a same layer and made of a same material as the second gate electrode layer of the display substrate 1, and/or at least one of the plurality of first sub-members 121 may be created from a same layer and made of a same material as the semiconductor layer of the display substrate 1.

To be specific, when at least one of the first sub-members 121 is created from a same layer and made of a same material as the first gate electrode layer of the display substrate 1, it is able to form the first gate electrode layer and the at least one of the first sub-members 121 through a single patterning process. When at least one of the first sub-members 121 is created from a same layer and made of a same material as the second gate electrode layer of the display substrate 1, it is able to form the second gate electrode layer and the at least one of the first sub-members 121 through a single patterning process. When at least one of the first sub-members 121 is created from a same layer and made of a same material as the semiconductor layer of the display substrate 1, it is able to form the semiconductor layer and the at least one of the first sub-members 121 through a single patterning process.

When the first sub-members 121 are provided as mentioned hereinabove, it is unnecessary to provide an additional process for forming the first sub-members 121, so it is able to reduce the manufacture cost of the barrier structure 12. In addition, when the first sub-members 121 are made of a same metallic material as the first gate electrode layer and the second gate electrode layer, it is able to provide the first sub-members 121 with better flexibility, thereby to prevent the first sub-members 121 from forming the channels for the spreading of the cracks.

It should be appreciated that, usually the semiconductor layer, the first gate electrode layer and the second gate electrode layer may be arranged in the conventional display substrate as follows. The semiconductor layer, the first gate electrode layer and the second gate electrode layer may be arranged sequentially on the base substrate of the display substrate in a direction away from the base substrate. Hence, when the first sub-members 121 of the barrier members 120 of the barrier structure are arranged at different layers and gradually close to the base substrate in the direction away from the functional region 10, taking three first sub-members 121 as an example, the first sub-member 121 closest to the functional region 10 may be created from a same layer and made of a same material as the second gate electrode layer, the first sub-member 121 furthest from the functional region 10 may be created from a same layer and made of a same material as the semiconductor layer, and the middle first sub-member 121 may be created from a same layer and made of a same material as the first gate electrode layer. When the three first sub-members 121 are arranged as mentioned above, it is unnecessary to provide any additional process for forming the first sub-members 121, so it is able to further reduce the manufacture cost of the barrier structure 12.

In addition, when each first sub-member 121 includes the first sub-pattern 1210 and the second sub-pattern 1211 arranged at different layers, the first sub-pattern 1210 may be created from a same layer and made of a same material as the first gate electrode layer, and the second sub-pattern 1211 may be created from a same layer and made of a same material as the second gate electrode layer; or the first sub-pattern 1210 may be created from a same layer and made of a same material as the semiconductor layer, and the second sub-pattern 1211 may be created from a same layer and made of a same material as the second gate electrode layer; or the first sub-pattern 1210 may be created from a same layer and made of a same material as the semiconductor layer, and the second sub-pattern 1211 may be created from a same layer and made of a same material as the first gate electrode layer.

In some embodiments of the present disclosure, the first connection layer 123 may be created from a same layer and made of a same material as the source electrode layer and the drain electrode layer of the display substrate 1, and the second connection layer 125 may be created from a same layer and made of a same material as the anode layer of the display substrate 1.

To be specific, when the first connection layer 123 is created from a same layer and made of a same material as the source electrode layer and the drain electrode layer of the display substrate 1, it is able to form the first connection layer 123 and the source/drain electrode layer of the display substrate 1 through a single patterning process, and when the second connection layer 125 is created from a same layer and made of a same material as the anode layer of the display substrate 1, it is able to form the second connection layer 125 and the anode layer of the display substrate 1 through a single patterning process.

When the first connection layer 123 and the second connection layer 125 are arranged as mentioned hereinabove, it is unnecessary to provide any additional processes for forming the first connection layer 123 and the second connection layer 125, thereby to reduce the manufacture cost of the barrier structure 12. In addition, when the first connection layer 123 is made of a same metallic material as the source electrode layer and the drain electrode layer and the second connection layer 125 is made of a same metallic material as the anode layer, it is able to provide the first connection layer 123 and the second connection layer 125 with better flexibility, thereby to prevent them from forming the channels for the spreading of the cracks.

In some embodiments of the present disclosure, the display substrate 1 may further include a dielectric layer and a planarization layer. The dielectric layer may be arranged at a side of each first sub-member 121 away from the base substrate and provided with a plurality of first via-holes 126, and the second sub-members 122 may be formed in the first via-holes 126 in a one-to-one manner. The planarization layer may be arranged at a side of the first connection layer 123 away from the base substrate and provided with a plurality of second via-holes 127, and the third sub-members 124 may be formed in the second via-holes 127 in a one-to-one manner.

To be specific, during the manufacture of the display substrate 1, the dielectric layer may be formed between any two adjacent layers of the semiconductor layer, the first gate electrode layer, the second gate electrode layer and a source/drain metal layer (including the source electrode layer and the drain electrode layer), and usually the dielectric layer may be formed as a whole layer. Hence, after the formation of the first sub-members 121, the dielectric layer may be formed on the first sub-members 121 and provided with the first via-holes 126, and then the second sub-members 122 may be formed in the first via-holes 126 respectively. In addition, after the formation of the source/drain metal layer, usually the planarization layer as a whole layer may be formed at a side of the source/drain metal layer away from the base substrate. Hence, after the formation of the first connection layer 123, the planarization layer may be formed on the first connection layer 123 and provided with the second via-holes 127, and then the third sub-members 124 may be formed in the second via-holes 127 respectively.

It should be appreciated that, the first sub-members 121 of the barrier structure 12 may be arranged at different layers. Taking three sub-members as an example, when the first sub-member 121 closest to the functional region 10 is created from a same layer and made of a same material as the second gate electrode layer, the first sub-member 121 furthest from the functional region 10 is created from a same layer and made of a same material as the semiconductor layer and the middle first sub-member 121 is created from a same layer and made of a same material as the first gate electrode layer, a first dielectric layer may be, after the formation of the first sub-member 121 furthest from the functional region 10, formed at a surface of the first sub-member 121 away from the base substrate, a second dielectric layer may be, after the formation of the middle first sub-member 121, formed at a surface of the first sub-member 121 away from the base substrate, and a third dielectric layer may be, after the formation of the first sub-member 121 closest to the functional region 10, formed at a surface of the first sub-member 121 away from the base substrate. Hence, during the formation of the first via-holes 126, the first via-hole 126 corresponding to the first sub-member 121 furthest from the functional region 10 needs to penetrate through the first dielectric layer, the second dielectric layer and the third dielectric layer, the first via-hole 126 corresponding to the middle first sub-member 121 needs to penetrate through the second dielectric layer and the third dielectric layer, and the first via-hole 126 corresponding to the first sub-member 121 closest to the functional region 10 merely needs to penetrate through the third dielectric layer.

Further, when the second sub-members 122 are formed in the first via-holes 126 respectively, the first connection layer 123 may be made of a same material as the second sub-members 122, and when the third sub-members 124 are formed in the second via-holes 127 respectively, the second connection layer 125 may be made of a same material as the third sub-members 124.

To be specific, when the second sub-members 122 are formed in the first via-holes 126 respectively, the first connection layer 123 may be made of a same material as the second sub-members 122, so as to form the second sub-members 122 and the first connection layer 123 through a single patterning process. Identically, when the third sub-members 124 are formed in the second via-holes 127 respectively, the second connection layer 125 may be made of a same material as the third sub-members 124, so as to form the third sub-members 124 and the second connection layer 125 through a single patterning process. In other words, when the first connection layer 123 is made of a same material as the second sub-members 122 and the second connection layer 125 is made of a same material as the third sub-members 124, it is able to further reduce the manufacture cost of the barrier structure 12.

The present disclosure further provides in some embodiments a display device including the above-mentioned display substrate 1.

According to the embodiments of the present disclosure, the barrier structure 12 may be arranged at the peripheral region 11 of the display substrate 1, and the barrier members 120 of the barrier structure 12 may stop the cracks many times. In addition, the barrier members 120 may not easily be broken when stopping the cracks, i.e., they may not form channels for the spreading of the cracks. As a result, when the display device includes the display substrate 1, it is able to provide a better crack-stopping effect.

The present disclosure further provides in some embodiments a manufacturing method for the above-mentioned display substrate which, as shown in FIGS. 2 to 4, includes forming the plurality of barrier members 120 at the peripheral region 11 of the display substrate 1. The plurality of barrier members 120 may be spaced apart from each other in the direction away from the functional region 10, and at least a part of the barrier member 120 may be made of metal.

To be specific, the plurality of barrier members 120 may be made of a metallic material at the peripheral region 11 of the display substrate 1. The plurality of barrier members 120 may be spaced apart from each other in the direction away from the functional region 10, and they may be equivalent to a plurality of retaining walls at the peripheral region 11 of the display substrate 1, so as to stop the cracks occurring at the periphery of the display substrate 1.

According to the manufacturing method in the embodiments of the present disclosure, the barrier structure 12 may be arranged at the peripheral region 11 and include the plurality of barrier members 120 spaced apart from each other in the direction away from the functional region 10, so when the cracks spread to the barrier structure 12, they may stopped by the barrier members 120 of the barrier structure 12 many times. In addition, at least a part of the barrier member 120 may be made of a metallic material having relatively high strength, excellent plasticity and flexibility, so the barrier member may not easily be broken when stopping the cracks, i.e., they may not form channels for the spreading of the cracks. As a result, it is able to provide the manufactured display substrate 1 with a better crack-stopping effect.

Further, when each barrier member 120 includes the first sub-member 121 and the second sub-member 122, the forming the plurality of barrier members 120 at the peripheral region 11 of the display substrate 1 may include forming the first sub-members 121 of the barrier members 120. The first sub-members 121 may be independent of each other. To be specific, the when the first sub-members 121 are arranged at a same layer, a metallic film layer may be formed using a metallic material, and then patterned to acquire the first sub-members 121 independent of each other. In addition, when the first sub-members 121 are arranged at different layers, the metallic film layers may be formed at different layers, and then patterned so as to acquire the first sub-members 121 at different layers.

Each second sub-member 122 may be formed at a surface of the corresponding first sub-member 121 away from the base substrate of the display substrate 1, and an orthogonal projection of each second sub-member 122 onto the base substrate may be located within an orthogonal projection of the corresponding first sub-member 121 onto the base substrate. To be specific, after the formation of the first sub-members 121, each second sub-member 122 may be formed at a surface of the corresponding first sub-member 121 away from the base substrate of the display substrate 1 using a metallic material.

As mentioned above, each barrier member 120 may include the first sub-member 121 and the second sub-member 122 laminated one on another. In this way, it is able to provide the barrier member 120 with a relatively large thickness in the direction perpendicular to the display substrate 1, thereby to provide a large stopping range in the direction perpendicular to the base substrate. In addition, when one of the first sub-member 121 and the second sub-member 122 is broken, the cracks may not easily spread to the other one, i.e., the other one of the first sub-member 121 and the second sub-member 122 may still stop the spreading of the cracks.

Further, when the display substrate 1 includes the first gate electrode layer, the second gate electrode layer and the semiconductor layer, the forming the first sub-members 121 of the barrier members 120 may include forming at least one of the first sub-members 121 and the first gate electrode layer through a single patterning process, forming at least one of the first sub-members 121 and the second gate electrode layer through a single patterning process, and/or forming at least one of the first sub-members 121 and the semiconductor layer through a single patterning process.

To be specific, a metallic thin film may be formed as a whole layer using a metallic material. Next, a photoresist may be applied onto the metallic thin film, and exposed and developed so as to form a photoresist reserved region corresponding to a region where the first sub-members 121 and the first gate electrode layer are located and a photoresist unreserved region corresponding to the other region. Next, the metallic thin film at the photoresist unreserved region may be etched through an etching process, so as to fully remove the metallic thin film at the photoresist unreserved region. Then, the photoresist at the photoresist reserved region may be removed, so as to form the first sub-members 121 and the first gate electrode layer.

To be specific, a metallic thin film may be formed as a whole layer using a metallic material. Next, a photoresist may be applied onto the metallic thin film, and exposed and developed so as to form a photoresist reserved region corresponding to a region where the first sub-members 121 and the second gate electrode layer are located and a photoresist unreserved region corresponding to the other region. Next, the metallic thin film at the photoresist unreserved region may be etched through an etching process, so as to fully remove the metallic thin film at the photoresist unreserved region. Then, the photoresist at the photoresist reserved region may be removed, so as to form the first sub-members 121 and the second gate electrode layer.

To be specific, a semiconductor thin film may be formed as a whole layer using a semiconductor material. Next, a photoresist may be applied onto the metallic thin film, and exposed and developed so as to form a photoresist reserved region corresponding to a region where the first sub-members 121 and the semiconductor layer are located and a photoresist unreserved region corresponding to the other region. Next, the semiconductor thin film at the photoresist unreserved region may be etched through an etching process, so as to fully remove the metallic thin film at the photoresist unreserved region. Then, the photoresist at the photoresist reserved region may be removed, so as to form the first sub-members 121 and the semiconductor layer.

When the first sub-members 121 are formed as mentioned hereinabove, it is unnecessary to provide any additional process for forming the first sub-members 121, so it is able to reduce the manufacture cost of the barrier structure 12. In addition, when the first sub-members 121 are made of a same metallic material as the first gate electrode layer and the second gate electrode layer, it is able to provide the first sub-members 121 with better flexibility, thereby to prevent the first sub-members 121 from forming the channels for the spreading of the cracks.

When the barrier structure 12 further includes the first connection layer 123 and the display substrate 1 further include the dielectric layer, prior to forming the second sub-members 122, the forming the barrier structure 12 at the peripheral region 11 of the display substrate may further include: forming the dielectric layer at a surface of each first sub-member 121 away from the base substrate of the display substrate 1; and patterning the dielectric layer to form the plurality of first via-holes 126.

To be specific, an insulating material may be deposited onto the surface of each first sub-member 121 away from the display substrate 1 to form the dielectric layer. It should be appreciated that, when the first sub-members 121 of the barrier structure 12 are arranged at different layers, after the formation of each layer of first sub-members 121, it is necessary to form the dielectric layer at the surface of the layer of first sub-members 121 away from the base substrate.

To be specific, the dielectric layer may be patterned through a patterning process so as to form the plurality of first via-holes 126. It should be appreciated that, the plurality of first via-holes 126 may correspond to the first sub-members 121 in a one-to-one manner, and an orthogonal projection of each first via-hole 126 onto the base substrate may be located within an orthogonal projection of the corresponding first sub-member 121 onto the base substrate.

Subsequent to forming the plurality of first via-holes 126, the forming each second sub-member 122 at the surface of the corresponding first sub-member 121 away from the base substrate of the display substrate 1 may include forming the plurality of second sub-members 122 and the first connection layer 123 through a single patterning process. The plurality of second sub-members 122 may be located in the plurality of first via-holes 126 in a one-to-one manner, and ends of the second sub-members 122 away from the corresponding first sub-members 121 may be connected through the first connection layer 123.

To be specific, after the formation of the first via-holes 126, a metallic material may be deposited onto a surface of the dielectric layer away from the base substrate, so as to fully fill the plurality of first via-holes 126. Next, a metallic film layer may be formed at the surface of the dielectric layer away from the base substrate, and then patterned, so as to form the plurality of second sub-members 122 in the first via-holes 126 respectively, and form the first connection layer 123 configured to connect the ends of the second sub-members 122 away from the corresponding first sub-members 121.

As mentioned above, it is able to form the second sub-members 122 and the first connection layer 123 through a single patterning process, thereby to reduce the manufacture cost of the barrier structure 12.

Further, when the display substrate 1 further includes the source electrode layer and the drain electrode layer, the forming the plurality of second sub-members 122 and the first connection layer 123 through a single patterning process may include forming the plurality of second sub-members 122, the first connection layer 123, the source electrode layer and the drain electrode layer through a single patterning process.

To be specific, a metallic material may be deposited to form a metallic thin film. Next, a photoresist may be applied to the metallic thin film, and exposed and developed to form a photoresist reserved region corresponding to a region where the second sub-members 122, the first connection layer 123, the source electrode layer and the drain electrode layer are located, and a photoresist unreserved region corresponding to the other region. Next, the metallic thin film at the photoresist unreserved region may be etched through an etching process, so as to fully remove the metallic thin film. Then, the photoresist at the photoresist reserved region may be fully removed, so as to form the plurality of second sub-members 122, the first connection layer 123, the source electrode layer and the drain electrode layer.

As mentioned above, it is able form the plurality of second sub-members 122, the first connection layer 123, the source electrode layer and the drain electrode layer through a single patterning process without any additional process for forming the second sub-members 122 and the first connection layer 123, thereby to further reduce the manufacture cost of the barrier structure 12.

When the barrier structure 12 further includes the third sub-members 124, subsequent to forming the first connection layer 123, the forming the barrier structure 12 at the peripheral region 11 of the display substrate may further include forming the plurality of third sub-members 124 at a side of the first connection layer away from the first sub-members 121. The third sub-members 124 may correspond to the first sub-members 121 in a one-to-one manner, and an orthogonal projection of each third sub-member 124 onto the base substrate may be located within the orthogonal projection of the corresponding first sub-member 121 onto the base substrate.

To be specific, after the formation of the first connection layer 123, the third sub-members 124 may be formed at a surface of the first connection layer 123 away from the base substrate of the display substrate 1 using a metallic material.

When the third sub-members 124 are formed as mentioned hereinabove, it is able to provide the third sub-members 124 with better flexibility, thereby to achieve a better crack-stopping effect. In addition, the third sub-members 124 may correspond to the first sub-members 121 in a one-to-one manner, and the orthogonal projection of each third sub-member 124 onto the base substrate may be located within the orthogonal projection of the corresponding first sub-member 121 onto the base substrate, so each first sub-member 121 of the barrier structure 12 may correspond to one second sub-member 122 and one third sub-member 124, and each first sub-member 121, the corresponding second sub-member 122 and the corresponding third sub-member 124 may form a straight line approximately in the direction perpendicular to the base substrate, so as to further improve the stopping effect of the barrier structure 12.

When the barrier structure 12 further includes the second connection layer 125 and the display substrate 1 further includes the planarization layer, subsequent to forming the first connection layer 123, the forming the barrier structure 12 at the peripheral region 11 of the display substrate 1 may further include: forming the planarization layer at the surface of the first connection layer 123 away from the display substrate 1; and patterning the planarization layer to form the plurality of second via-holes 127.

To be specific, after the formation of the source electrode layer and the drain electrode layer of the display substrate 1 as well as the second connection layer 125 of the barrier structure 21, the planarization layer may be deposited onto a surface of each of the source electrode layer, the drain electrode layer and the second connection layer 125 away from the base substrate.

To be specific, the planarization layer may be patterned through a patterning process, so as to form the plurality of second via-holes 127 in the planarization layer. It should be appreciated that, the plurality of second via-holes 127 may correspond to the plurality of third sub-members 124 in a one-to-one manner. An orthogonal projection of each second via-hole 127 onto the base substrate may be located within the orthogonal projection of the corresponding first sub-member 121 onto the base substrate.

Subsequent to forming the plurality of second via-holes 127, the forming the plurality of third sub-members 124 at the surface of the first connection layer 123 away from the first sub-members 121 may include forming the plurality of third sub-members 124 and the second connection layer 125 through a single patterning process. The plurality of third sub-members 124 may be arranged in the plurality of second via-holes 127 in a one-to-one manner, and ends of the third sub-members 124 away from the corresponding first sub-members 121 may be connected through the second connection layer 125.

To be specific, after the formation of the plurality of second via-holes 127, a metallic material may be deposited onto a surface of the planarization layer away from the base substrate so as to fully fill the plurality of second via-holes 127. Next, a metallic film layer may be formed at a surface of the planarization layer away from the base substrate, and then patterned, so as to form the plurality of third sub-members 124 located in the plurality of second via-holes 127 respectively, and form the second connection layer 125 for connecting the ends of the third sub-members 124 away from the corresponding first sub-members 121.

As mentioned above, it is able to form the third sub-members 124 and the second connection layer 125 through a single patterning process, thereby to reduce the manufacture cost of the barrier structure 12.

When the display substrate 1 further includes the anode layer, the forming the third sub-members 124 and the second connection layer 125 through a single patterning process may include forming the third sub-members 124, the second connection layer 125 and the anode layer through a single patterning process.

To be specific, after the formation of the plurality of second via-holes 127, a metallic material may be deposited onto the surface of the planarization layer away from the base substrate to fully fill the plurality of second via-holes 127. Then, a metallic film layer may be formed at a surface of the planarization layer away from the base substrate, and then patterned, so as to form the anode layer, the plurality of third sub-members 124 located in the plurality of second via-holes 127 respectively, and the second connection layer 125 for connecting the ends of the third sub-members 124 away from the corresponding first sub-members 121.

As mentioned above, it is able to form the plurality of third sub-members 124, the second connection layer 125 and the anode layer through a single patterning process without any additional process for forming the third sub-members 124 and the second connection layer 125, thereby to further reduce the manufacture cost of the barrier structure 12.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

The features, structures or materials may be combined in any embodiment or embodiments in an appropriate manner. In the case of no conflict, the embodiments or examples or the features therein may be combined in any form.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising a functional region and a peripheral region surrounding the functional region, wherein a barrier structure is arranged at the peripheral region of the display substrate, and comprises a plurality of barrier members spaced from each other in a direction away from the functional region, at least a part of the barrier member is made of metal, and thicknesses of the barrier members in a direction perpendicular to the display substrate gradually increase in the direction away from the functional region.

2. The display substrate according to claim 1, wherein each barrier member comprises a first sub-member and a second sub-member laminated one on another, the second sub-member is located at a surface of the first sub-member away from a base substrate of the display substrate, and an orthogonal projection of the second sub-member onto the base substrate is located within an orthogonal projection of the first sub-member onto the base substrate.

3. The display substrate according to claim 2, wherein the first sub-members of the barrier members are independent of each other, and the barrier structure further comprises a first connection layer configured to connect ends of the second sub-members away from the corresponding first sub-members.

4. The display substrate according to claim 3, wherein the barrier structure further comprises a plurality of third sub-members arranged at a side of the first connection layer away from the first sub-members and corresponding to the first sub-members in a one-to-one manner, and an orthogonal projection of each third sub-member onto the base substrate is located within the orthogonal projection of the corresponding first sub-member onto the base substrate.

5. The display substrate according to claim 4, wherein the barrier structure further comprises a second connection layer configured to connect ends of the third sub-members away from the corresponding first sub-members.

6. The display substrate according to claim 5, wherein the first sub-members, the second sub-members, the third sub-members, the first connection layer and/or the second connection layer surround the functional region.

7. The display substrate according to claim 5, wherein an orthogonal projection of each of the first sub-members, the second sub-members, the third sub-members, the first connection layer and/or the second connection layer onto the base substrate of the display substrate is of a wave shape.

8. The display substrate according to claim 4, wherein each first sub-member comprises a first sub-pattern and a second sub-pattern arranged at a same layer or different layers, and an orthogonal projection of the first sub-pattern onto the base substrate and an orthogonal projection of the second sub-pattern onto the base substrate together define at least one enclosed region.

9. The display substrate according to claim 2, wherein the first sub-members of the barrier members of barrier structure are arranged at different layers and gradually close to the base substrate in the direction away from the functional region, and thicknesses of the second sub-members in the direction perpendicular to the display substrate gradually increase in the direction away from the functional region.

10. The display substrate according to claim 9, wherein at least one of the plurality of first sub-members is created from a same layer and made of a same material as a first gate electrode layer of the display substrate, at least one of the plurality of first sub-members is created from a same layer and made of a same material as a second gate electrode layer of the display substrate, and/or at least one of the plurality of first sub-members is created from a same layer and made of a same material as a semiconductor layer of the display substrate.

11. The display substrate according to claim 5, wherein the first connection layer is created from a same layer and made of a same material as a source electrode layer and a drain electrode layer of the display substrate, and the second connection layer is created from a same layer and made of a same material as an anode layer of the display substrate.

12. The display substrate according to claim 5, further comprising:
a dielectric layer arranged at a side of each first sub-member away from the base substrate and provided with a plurality of first via-holes, the second sub-members being formed in the first via-holes in a one-to-one manner; and
a planarization layer arranged at a side of the first connection layer away from the base substrate and provided with a plurality of second via-holes, the third sub-members being formed in the second via-holes in a one-to-one manner.

13. The display substrate according to claim 12, wherein the first connection layer is made of a same material as each second sub-member, and the second connection layer is made of a same material as each third sub-member.

14. A display device, comprising the display substrate according to claim 1.

15. A method of manufacturing the display substrate according to claim 1, comprising forming a barrier structure at a peripheral region of the display substrate, wherein the barrier structure of the display substrate comprises a plurality of barrier member, each barrier member comprises a first sub-member and a second sub-member, and the display substrate further comprises a first gate electrode layer, a second gate electrode layer, and a semiconductor layer, wherein the forming the barrier structure at the peripheral region of the display substrate comprises:
forming at least one of the plurality of first sub-members and the first gate electrode layer through a single patterning process;
forming at least one of the plurality of first sub-members and the second gate electrode layer through a single patterning process; and/or
forming at least one of the plurality of first sub-members and the semiconductor layer through a single patterning process, the first sub-members of the barrier members being spaced from each other; and
forming each second sub-member at a surface of the corresponding first sub-member away from a base substrate of the display substrate, an orthogonal projection of each second sub-member onto the base substrate being located within an orthogonal projection of the corresponding first sub-member onto the base substrate.

16. The method according to claim 15, wherein the barrier structure further comprises a first connection layer, and the display substrate further comprises a dielectric layer, wherein prior to forming the second sub-members, the forming the barrier structure at the peripheral region of the display substrate further comprises:
forming the dielectric layer at a surface of each first sub-member away from the base substrate of the display substrate; and
patterning the dielectric layer to form a plurality of first via-holes, and
wherein the forming each second sub-member at the surface of the corresponding first sub-member away from the base substrate of the display substrate comprises forming the plurality of second sub-members and the first connection layer through a single patterning process, the plurality of second sub-members is located within the plurality of first via-holes in a one-to-one manner, and the first connection layer is configured to connect ends of the plurality of second sub-members away from the corresponding first sub-members.

17. The method according to claim 16, wherein the display substrate further comprises a source electrode layer and a drain electrode layer, and the forming the plurality of second sub-members and the first connection layer through a single patterning process comprises forming the plurality of second sub-members, the first connection layer, the source electrode layer and the drain electrode layer through a single patterning process.

18. The method according to claim 16 or 17, wherein the barrier structure further comprises a plurality of third sub-members and a second connection layer, and the display substrate further comprises a planarization layer, wherein subsequent to forming the first connection layer, the forming the barrier structure at the peripheral region of the display substrate further comprises:
forming the planarization layer at a surface of the first connection layer away from the base substrate of the display substrate;
patterning the planarization layer to form a plurality of second via-holes corresponding to the first sub-members in a one-to-one manner, an orthogonal of each second via-hole onto the base substrate being located within an orthogonal projection of the corresponding first sub-member onto the base substrate; and
forming the plurality of third sub-members and the second connection layer through a single patterning process, the plurality of third sub-members being located within the plurality of second via-holes in a one-to-one manner, and the second connection layer being configured to connect ends of the plurality of third sub-members away from the corresponding first sub-members.

19. The method according to claim 18, wherein the display substrate further comprises an anode layer, and the forming the plurality of third sub-members and the second connection layer through a single patterning process comprises forming the plurality of third sub-members, the second connection layer and the anode layer through a single patterning process.
